(19) United States
(12) Patent Application Publication
(10) Pub. No.: US 2026/0096205 A1
(43) Pub. Date: Apr. 2, 2026

(54) SEMICONDUCTOR DEVICE

(71) Applicant: Samsung Electronics Co., Ltd., Suwon-si (KR)

(72) Inventors: Jaeho JEON, Suwon-si (KR); Byungho MOON, Suwon-si (KR); Donghoon HWANG, Suwon-si (KR)

(73) Assignee: Samsung Electronics Co., Ltd., Suwon-si (KR)

(21) Appl. No.: 19/304,696

(22) Filed: Aug. 20, 2025

(30) Foreign Application Priority Data
Oct. 2, 2024 (KR) 10-2024-0133959

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

Provided is a semiconductor device including a first channel pattern and a second channel pattern at least partially overlapping, a first gate pattern between the first channel pattern and the second channel pattern, and at least partially overlapping the first channel pattern and the second channel pattern, a first connection conductive pattern and a second connection conductive pattern spaced apart from each other in a first direction, and the first channel pattern, the second channel pattern, and the first gate pattern between the first and second connection conductive patterns, and a first source/drain pattern connected to the first channel pattern and the second channel pattern. The first connection conductive pattern and the second connection conductive pattern are electrically connected to the first gate pattern.

### CROSS-REFERENCE TO RELATED APPLICATIONS

This U.S. non-provisional patent application claims priority under 35 U.S.C. § 119 of Korean Patent Application No. 10-2024-0133959, filed on Oct. 2, 2024, the entire contents of which are hereby incorporated by reference.

### BACKGROUND

Example embodiments of the present disclosure herein relate to a semiconductor device, and more particularly, to a semiconductor device including a channel pattern.

A semiconductor device may include an integrated circuit composed of metal-oxide-semiconductor field effect transistors (MOSFET). As size and a design rules of the semiconductor device are continually decreasing, scaling down of the metal-oxide-semiconductor field effect transistors is also being accelerated. As the metal-oxide-semiconductor field effect transistors are scaled down, operational characteristics of the semiconductor device may be deteriorated. Accordingly, research on various methods for overcoming limitations caused by higher-integration of semiconductor devices is being conducted for forming semiconductor devices with improved performance.

### SUMMARY

Example embodiments of the present disclosure provide a semiconductor device with improved electrical characteristics and reliability.

Some example embodiments of the inventive concepts provide a semiconductor device including a first channel pattern and a second channel pattern at least partially overlapping, a first gate pattern between the first channel pattern and the second channel pattern, and at least partially overlapping the first channel pattern and the second channel pattern, a first connection conductive pattern and a second connection conductive pattern spaced apart from each other in a first direction, and the first channel pattern, the second channel pattern, and the first gate pattern between the first and second connection conductive patterns, and a first source/drain pattern connected to the first channel pattern and the second channel pattern. The first connection conductive pattern and the second connection conductive pattern are electrically connected to the first gate pattern.

In some example embodiments of the inventive concepts, a semiconductor device includes a first channel pattern and a second channel pattern at least partially overlapping, a first gate pattern between the first channel pattern and the second channel pattern, and overlapping the first channel pattern and the second channel pattern, a first connection conductive pattern spaced apart from the first channel pattern and the second channel pattern, and electrically connected to the first gate pattern, and a source/drain pattern connected to the first channel pattern and the second channel pattern. The first channel pattern, the second channel pattern, and the first gate pattern are between an upper surface and a lower surface of the first connection conductive pattern.

In some example embodiments of the inventive concepts, a semiconductor device includes a first channel pattern and a second channel pattern at least partially overlapping, a first gate pattern between the first channel pattern and the second channel pattern, and at least partially overlapping the first channel pattern and the second channel pattern, a first connection conductive pattern and a second connection conductive pattern spaced apart from each other in a first direction, and the first channel pattern, the second channel pattern, and the first gate pattern between the first and second connection conductive patterns, a first source/drain pattern connected to the first channel pattern and the second channel pattern, a third channel pattern spaced apart from the first channel pattern in the first direction, a fourth channel pattern spaced apart from the second channel pattern in the first direction, and overlapping the third channel pattern, a second gate pattern between the third channel pattern and the fourth channel pattern, overlapping the third channel pattern and the fourth channel pattern, and spaced apart from the first gate pattern in the first direction, a third connection conductive pattern and a fourth connection conductive pattern spaced apart from each other in the first direction, and the third channel pattern, the fourth channel pattern and the second gate pattern between the third and fourth connection conductive patterns, a second source/drain pattern connected to the third channel pattern and the fourth channel pattern, a first spacer at least partially overlapping the first and second source/drain patterns, a first mask pattern at least partially overlapping the first channel pattern, the second channel pattern, and the first gate pattern, a second mask pattern at least partially overlapping the third channel pattern, the fourth channel pattern and the second gate pattern, a second spacer on the first and second mask patterns and the first spacer, and a cover insulating layer on the first and second mask patterns and the first to fourth connection conductive patterns.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and, together with the description, serve to explain principles of the inventive concepts. In the drawings:

FIG. 1A is a plan view of a semiconductor device according to some example embodiments;

FIG. 1B is a cross-sectional view taken along line A-A′ of FIG. 1A;

FIG. 1C is a cross-sectional view taken along line B-B′ of FIG. 1A;

FIG. 1D is a cross-sectional view taken along line C-C′ of FIG. 1A;

FIG. 1E is a cross-sectional view taken along line D-D′ of FIG. 1A;

FIG. 1F is an enlarged view of region Q1 of FIG. 1A;

FIG. 1G is an enlarged view of region Q2 of FIG. 1B;

FIG. 1H is an enlarged view of region Q3 of FIG. 1C;

FIGS. 2, 3A, 3B, 4A, 4B, 5, 6A, 6B, 6C, 7A, 7B, 7C, 7D, 8A, 8B, 8C, 9A, 9B, 9C, 10A, 10B, 10C, 11A, 11B, 12A, 12B, 12C, 13A, 13B, 13C, 14A, 14B, 14C and 14D are diagrams for describing a method for manufacturing the semiconductor device according to FIGS. 1A to 1H;

FIGS. 15A, 15B and 15C are cross-sectional views of a semiconductor device according to some example embodiments;

FIGS. 16A and 16B are enlarged cross-sectional views of a semiconductor device according to some example embodiments; and

FIG. 17 is a cross-sectional view of a semiconductor device according to some example embodiments.

### DETAILED DESCRIPTION

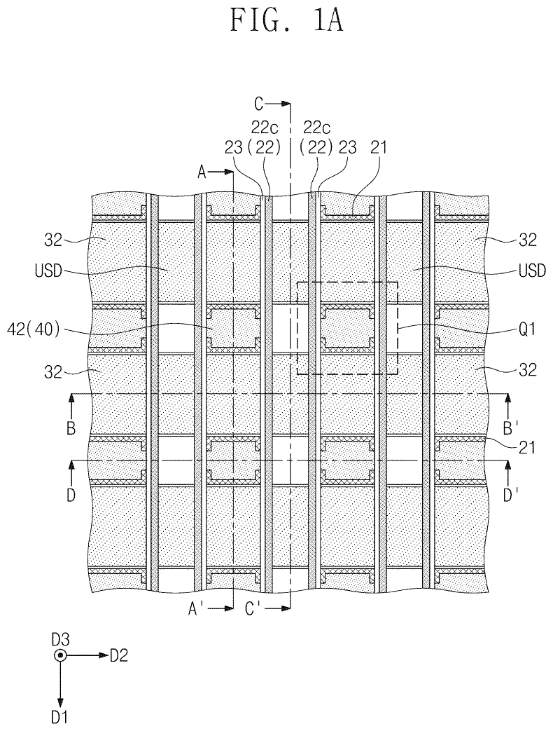

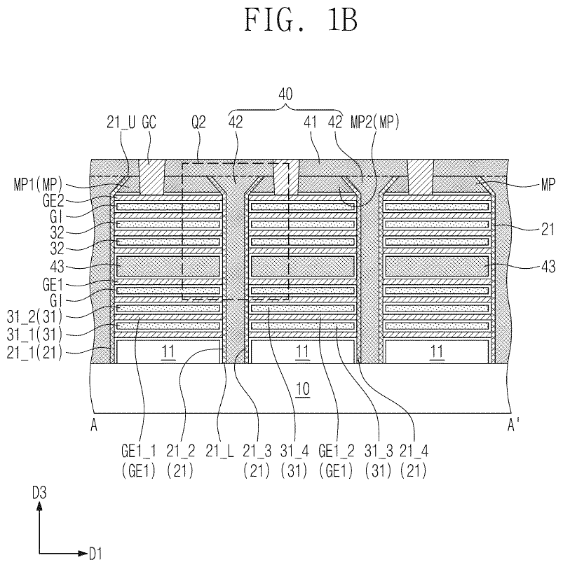

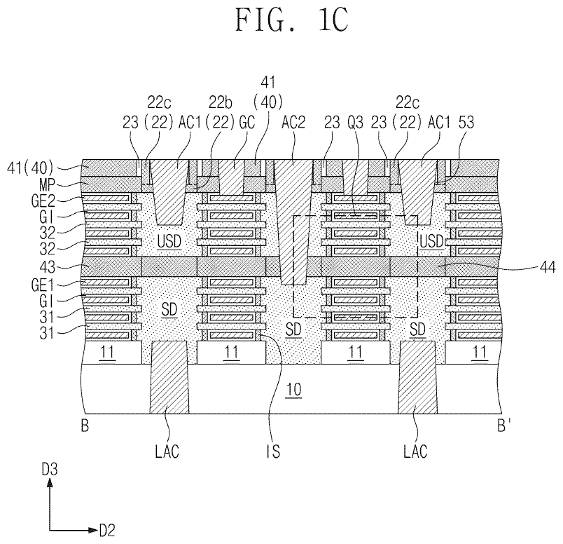

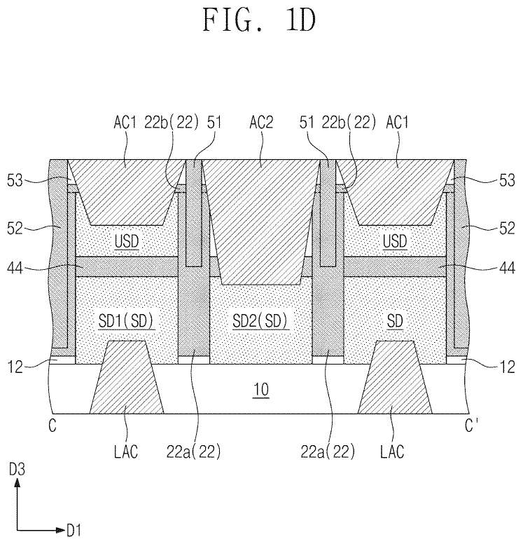

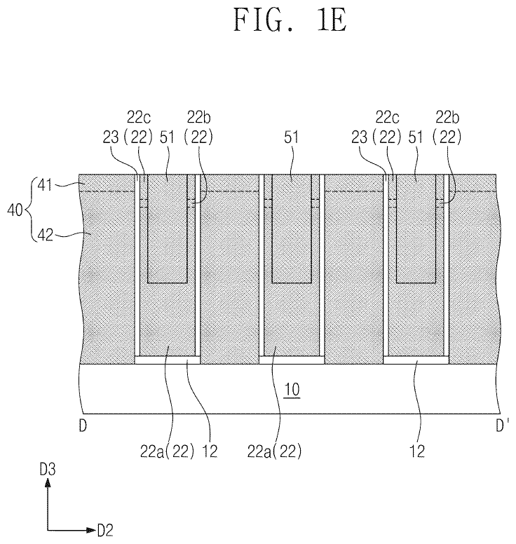

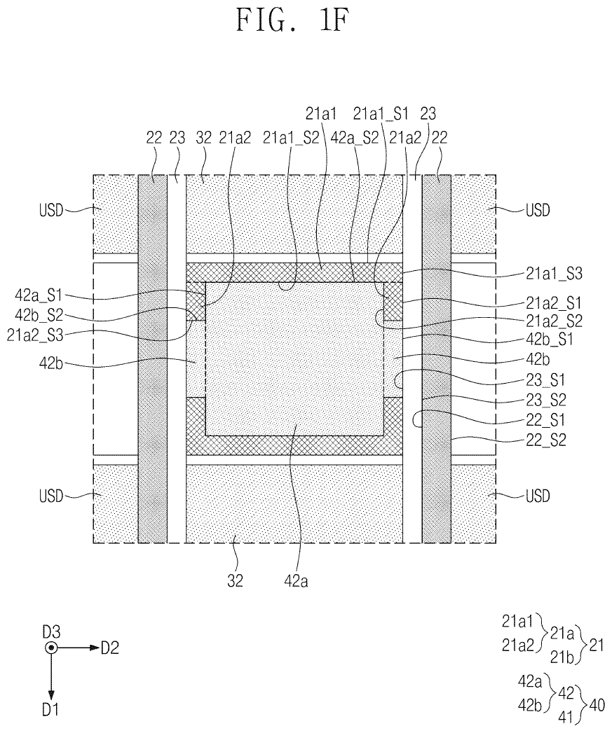

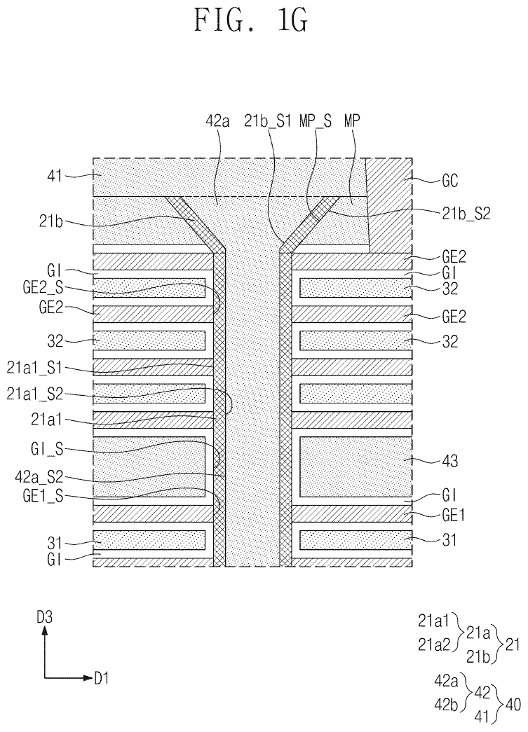

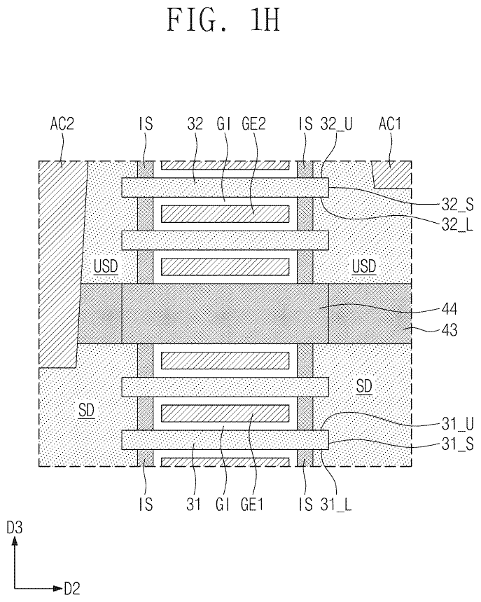

FIG. 1A is a plan view of a semiconductor device according to some example embodiments. FIG. 1B is a cross-sectional view taken along line A-A′ of FIG. 1A. FIG. 1C is a cross-sectional view taken along line B-B′ of FIG. 1A. FIG. 1D is a cross-sectional view taken along line C-C′ of FIG. 1A. FIG. 1E is a cross-sectional view taken along line D-D′ of FIG. 1A. FIG. 1F is an enlarged view of region Q1 of FIG. 1A. FIG. 1G is an enlarged view of region Q2 of FIG. 1B. FIG. 1H is an enlarged view of region Q3 of FIG. 1C.

Referring to FIGS. 1A, 1B, 1C, 1D and 1E, the semiconductor device may include a substrate 10. Logic cells may be disposed on the substrate 10. In some example embodiments of the present disclosure, the logic cell may mean a logical element (for example, AND, OR, XOR, XNOR, an inverter, or the like) that performs a specific function. The logic cell may include transistors for constituting the logical element.

The substrate 10 may be a semiconductor substrate, an insulating substrate, or a silicon-on-insulator (SOI) substrate. For example, the semiconductor substrate may include silicon, germanium, silicon-germanium, GaP, or GaAs. The substrate 10 may have a shape of a plate expanding along a plane expanding in a first direction D1 and a second direction D2. The first direction D1 and the second direction D2 may cross each other. For example, the first direction D1 and the second direction D2 may be horizontal directions perpendicular to each other.

According to some example embodiments, the semiconductor device may not include the substrate 10.

Insulating patterns 11 may be provided on the substrate 10. The insulating patterns 11 may include insulating patterns 11 arranged in the first direction D1. The insulating patterns 11 may include the insulating patterns 11 arranged in the second direction D2. The insulating patterns 11 may include an insulating material. For example, the insulating patterns 11 may include oxide.

According to some example embodiments, the semiconductor device may not include the insulating patterns 11, and the substrate 10 may include active patterns protruding in a third direction D3. The active pattern may be disposed in a position in which the insulating pattern 11 is disposed. The third direction D3 may cross the first direction D1 and the second direction D2. For example, the third direction D3 may be a vertical direction perpendicular to the first direction D1 and the second direction D2.

Interposed patterns 12 may be provided on the substrate 10. The interposed patterns 12 may include interposed patterns 12 arranged in the first direction D1. The interposed patterns 12 may include the interposed patterns 12 arranged in the second direction D2. The interposed patterns 12 may include an insulating material.

Channel patterns 31 may be provided. The channel patterns 31 may overlap the insulating pattern 11 in the third direction D3. One insulating pattern 11 and a plurality of channel patterns 31 may overlap each other in the third direction D3.

The channel pattern 31 may include a semiconductor material. For example, the channel pattern 31 may include a two-dimensional semiconductor material (for example, WSe MoS₂, black phosphorous (BP)). According to some example embodiments, the channel pattern 31 may be a monoatomic layer.

A number of the channel patterns 31 overlapping each other in the third direction D3 may not be limited to what is illustrated. According to some example embodiments, the number of the channel patterns 31 overlapping each other in the third direction D3 may be two or less, or four or more.

Source/drain patterns SD may be provided. The source/drain pattern SD may be disposed between the channel patterns 31 spaced apart from each other in the second direction D2. The source/drain pattern SD may be connected to the channel patterns 31 overlapping each other in the third direction D3. The channel patterns 31 overlapping each other in the third direction D3 may be disposed between the source/drain patterns SD spaced apart from each other in the second direction D2. The source/drain pattern SD may be disposed between the interposed patterns 12 adjacent to each other in the first direction D1.

The source/drain pattern SD may be an epitaxial pattern formed in a selective epitaxial growth (SEG) process. The source/drain pattern SD may include silicon or silicon-germanium. However, example embodiments are not limited thereto. The source/drain pattern SD may be doped with an impurity.

Gate patterns GE1 may be provided. The gate pattern GE1 may overlap the insulating pattern 11 and the channel pattern 31 in the third direction D3. One insulating pattern 11, a plurality of gate patterns GE1 and a plurality of channel patterns 31 may overlap each other in the third direction D3. The channel pattern 31 may be disposed between the gate patterns GE1. The channel pattern 31 and the gate pattern GE1 may be spaced apart from each other.

The gate pattern GE1 may include a conductive material. For example, the gate pattern GE1 may include TiAlC or TiN. However, example embodiments are not limited thereto.

Upper channel patterns 32 may be provided. The upper channel pattern 32 may overlap the insulating pattern 11, the channel pattern 31 and the gate pattern GE1 in the third direction D3. One insulating pattern 11, a plurality of channel patterns 31, a plurality of gate patterns GE1 and a plurality of upper channel patterns 32 may overlap each other in the third direction D3. The upper channel patterns 32 may be disposed at a higher level than the channel patterns 31 and the gate patterns GE1.

The upper channel pattern 32 may include a semiconductor material. For example, the upper channel pattern 32 may include a two-dimensional semiconductor material (for example, WSe2, MoS2, or black phosphorous (BP)). However, example embodiments are not limited thereto. The upper channel pattern 32 and the channel pattern 31 may include the same material, or may respectively include different materials. According to some example embodiments, the upper channel pattern 32 may be a monoatomic layer.

A number of the upper channel patterns 32 overlapping each other in the third direction D3 may not be limited to what is illustrated. According to some example embodiments, the number of the upper channel patterns 32 overlapping each other in the third direction D3 may be two or less, or four or more.

Upper source/drain patterns USD may be provided. The upper source/drain pattern USD may be disposed between the upper channel patterns 32 spaced apart from each other in the second direction D2. The upper source/drain pattern USD may be connected to the upper channel patterns 32 overlapping each other in the third direction D3. The upper channel patterns 32 overlapping each other in the third direction D3 may be disposed between the upper source/drain patterns USD spaced apart from each other in the second direction D2. The upper source/drain pattern USD may be disposed at a higher level than the source/drain pattern SD.

The upper source/drain pattern USD may be an epitaxial pattern formed in a selective epitaxial growth (SEG) process. The upper source/drain pattern USD may include silicon or silicon-germanium. However, example embodiments are not limited thereto. The upper source/drain pattern USD may be doped with an impurity. The source/drain pattern SD and the upper source/drain pattern USD may respectively have different conductive types. For example, the source/drain pattern SD may have an N type conductive type, and the upper source/drain pattern USD may have a P type conductive type. However, example embodiments are not limited thereto.

Upper gate patterns GE2 may be provided. The upper gate pattern GE2 may overlap the insulating pattern 11, the channel pattern 31, the gate pattern GE1 and the upper channel pattern 32 in the third direction D3. One insulating pattern 11, a plurality of gate patterns GE1, a plurality of channel patterns 31, a plurality of upper channel patterns 32 and a plurality of upper gate patterns GE2 may overlap each other in the third direction D3. The upper channel pattern 32 may be disposed between the upper gate patterns GE2. The upper channel pattern 32 and the upper gate pattern GE2 may be spaced apart from each other. The upper gate patterns GE2 may be disposed at a higher level than the channel patterns 31 and the gate patterns GE1.

The upper gate pattern GE2 may include a conductive material. For example, the upper gate pattern GE2 may include TiAlC or TiN. However, example embodiments are not limited thereto. The gate pattern GE1 and the upper gate pattern GE2 may include the same material, or may respectively include different materials.

Gate insulating layers GI may be provided. The gate insulating layer GI may be in contact with the gate pattern GE1 and the channel pattern 31, or the upper gate pattern GE2 and the upper channel pattern 32. The channel pattern 31 and the gate pattern GE1 may be spaced apart from each other by the gate insulating layer GI. The upper channel pattern 32 and the upper gate pattern GE2 may be spaced apart from each other by the gate insulating layer GI. The gate insulating layer GI may include an insulating material. For example, the gate insulating layer GI may include oxide. However, example embodiments are not limited thereto.

Inner spacers IS may be provided. The inner spacer IS may be disposed between the source/drain pattern SD and the gate pattern GE1, or the upper source/drain pattern USD and the upper gate pattern GE2. The inner spacer IS and the gate pattern GE1 or the upper gate pattern GE2 may be spaced apart from each other by the gate insulating layer GI. The upper channel pattern 32 may be provided between the inner spacers IS spaced apart from each other in the third direction D3. The channel pattern 31 may be provided between the inner spacers IS spaced apart from each other in the third direction D3. The inner spacer IS may include an insulating material.

First interlayer insulating patterns 43 may be provided. The first interlayer insulating pattern 43 may overlap the insulating pattern 11, the channel pattern 31, the gate pattern GE1, the upper channel pattern 32 and the upper gate pattern GE2 in the third direction D3. The first interlayer insulating pattern 43 may be disposed between the channel pattern 31 and the upper channel pattern 32, and between the gate pattern GE1 and the upper gate pattern GE2. The first interlayer insulating patterns 43 may include an insulating material.

Second interlayer insulating patterns 44 may be provided. The second interlayer insulating pattern 44 may overlap the source/drain pattern SD and the upper source/drain pattern USD in the third direction D3. The second interlayer insulating pattern 44 may be disposed between the source/drain pattern SD and the upper source/drain pattern USD. The second interlayer insulating pattern 44 may include an insulating material.

The first interlayer insulating patterns 43 and the second interlayer insulating patterns 44 may be alternately arranged in the second direction D2.

Mask patterns MP may be provided. The mask pattern MP may overlap the insulating pattern 11, the channel pattern 31, the gate pattern GE1, the upper channel pattern 32 and the upper gate pattern GE2 in the third direction D3. One mask pattern MP, one insulating pattern 11, a plurality of gate patterns GE1, a plurality of channel patterns 31, a plurality of upper channel patterns 32 and a plurality of upper gate patterns GE2 may overlap each other in the third direction D3.

The mask pattern MP may be disposed at a higher level than the upper channel pattern 32 and the upper gate pattern GE2. The mask pattern MP may be provided on the gate insulating layer GI. A lower surface of the mask pattern MP may be in contact with the gate insulating layer GI. The mask pattern MP may include an insulating material. For example, the mask pattern MP may include nitride.

Connection conductive patterns 21 may be provided. The mask pattern MP, the insulating pattern 11, the channel patterns 31, the upper channel patterns 32, the gate patterns GE1 the upper gate patterns GE2 and the gate insulating layers GI overlapping each other in the third direction D3 may be provided between two connection conductive patterns 21 spaced apart from each other in the first direction D1. The connection conductive pattern 21 may be electrically connected to the gate patterns GE1 and the upper gate patterns GE2. The connection conductive pattern 21 may be in contact with the gate patterns GE1 and the upper gate patterns GE2. The connection conductive patterns 21 may be in contact with the mask pattern MP and the gate insulating layer GI. The channel pattern 31 and the upper channel pattern 32 may be spaced apart from the connection conductive pattern 21 by the gate insulating layer GI.

A lower surface 21_L of the connection conductive pattern 21 may be in contact with the substrate 10. The lower surface 21_L of the connection conductive pattern 21 may be substantially coplanar with a lower surface of the insulating pattern 11. An upper surface 21_U of the connection conductive pattern 21 may be substantially coplanar with an upper surface of the mask pattern MP. The upper surface 21_U of the connection conductive patterns 21 may be in contact with a cover insulating layer 40 to be described later. The mask pattern MP, the insulating pattern 11, the channel patterns 31, the upper channel patterns 32, the gate patterns GE1, the upper gate patterns GE2 and the gate insulating layers GI may be provided between the lower surface 21_L and the upper surface 21_U of the connection conductive pattern 21. The upper surface 21_U of the connection conductive pattern 21 may be an uppermost portion of the connection conductive pattern 21. The lower surface 21_L of the connection conductive pattern 21 may be a lowermost portion of the connection conductive pattern 21.

The connection conductive pattern 21 may include a conductive material different from the gate pattern GE1 and the upper gate pattern GE2. For example, the connection conductive pattern 21 may include a two-dimensional conductive material. For example, the connection conductive pattern 21 may include graphene or transition metal chalcogenide. However, example embodiments are not limited thereto. According to some example embodiments, the connection conductive pattern 21 may be a monoatomic layer.

The cover insulating layer 40 may be provided on the connection conductive patterns 21 and the mask patterns MP. The cover insulating layer 40 may include interposed portions 42 and an upper portion 41 connecting the interposed portions 42. The interposed portions 42 of the cover insulating layer 40 may be disposed at a lower level than the upper portion 41 of the cover insulating layer 40. The interposed portions 42 may be provided between the connection conductive patterns 21 adjacent to each other in the first direction D1. The interposed portions 42 may be in contact with two connection conductive patterns 21. The upper portion 41 of the cover insulating layer 40 may be in contact with an upper surface of the mask pattern MP. The cover insulating layer 40 may include an insulating material. For example, the cover insulating layer 40 may include nitride. However, example embodiments are not limited thereto.

First spacers 22 may be provided. The first spacer 22 may be provided on the source/drain patterns SD and the upper source/drain patterns USD. The first spacer 22 may overlap the upper source/drain patterns USD and the source/drain patterns SD in the third direction D3.

The first spacer 22 may include first parts 22a, a second part 22b on the first parts 22a, and third parts 22c on the second pars 22b. The first part 22a of the first spacer 22 may be provided between the source/drain patterns SD adjacent to each other in the first direction D1, and between the upper source/drain patterns USD adjacent to each other in the first direction D1. The first part 22a of the first spacer 22 may be in contact with the source/drain patterns SD adjacent to each other in the first direction D1, and the upper source/drain patterns USD adjacent to each other in the first direction D1. A width in the first direction D1 of the first part 22a of the first spacer 22 may be the same as a distance in the first direction D1 between the source/drain patterns SD adjacent to each other in the first direction D1, and a distance in the first direction D1 between the upper source/drain patterns USD adjacent to each other in the first direction D1. The first part 22a of the first spacer 22 may be provided on the interposed patterns 12.

The third parts 22c of the first spacer 22 may be spaced apart from each other in the second direction D2. The first spacer 22 may include an insulating material.

Second spacers 23 may be provided. The second spacer 23 may be provided on the first spacer 22 and the mask pattern MP. The second spacer 23 may extend in the first direction D1. The third parts 22c of the first spacer 22 may be provided between the second spacers 23 adjacent to each other in the second direction D2. The second spacer 23 may include an insulating material.

A filling insulating layer 53 may be provided. The filling insulating layer 53 may be provided on the first spacer 22. The filling insulating layer 53 may be provided between the third parts 22c of the first spacer 22. The filling insulating layer 53 may include an insulating material.

First separation insulating layers 51 and second separation insulating layers 52 may be provided. The first separation insulating layer 51 may penetrate the second part 22b of the first spacer 22 in the third direction D3. A lower portion of the first separation insulating layer 51 may be provided in the first part 22a of the first spacer 22. The first separation insulating layer 51 may overlap the first part 22a of the first spacer 22 in the third direction D3. The second separation insulating layer 52 may penetrate the second part 22b of the first spacer 22 in the third direction D3. A lower portion of the second separation insulating layer 52 may be provided in the first part 22a of the first spacer 22. The second separation insulating layer 52 may overlap the first part 22a of the first spacer 22 in the third direction D3. A length in the third direction D3 of the first separation insulating layer 51 may be smaller than a length in the third direction D3 of the second separation insulating layer 52. The first and second separation insulating layers 51 and 52 may include an insulating material.

Active contacts AC1 and AC2 may be provided. The active contacts AC1 and AC2 may include a first active contact AC1 and a second active contact AC2. The first active contact AC1 may penetrate the filling insulating layer 53 and the second part 22b of the first spacer 22 in the third direction D3. The first active contact AC1 may be in contact with the upper source/drain pattern USD. The second active contact AC2 may penetrate the filling insulating layer 53, the second part 22b of the first spacer 22, the upper source/drain pattern USD and the second interlayer insulating pattern 44 in the third direction D3. The second active contact AC2 may be in contact with the source/drain patters SD and the upper source/drain pattern USD. The active contacts AC1 and AC2 may include a conductive material.

Gate contacts GC may be provided. The gate contact GC may penetrate the upper portion 41 of the cover insulating layer 40, the mask pattern MP and the gate insulating layer GI in the third direction D3. The gate contacts GC may be in contact with the upper gate pattern GE2. The gate contact GC may include a conductive material.

Lower active contacts LAC may be provided. The lower active contact LAC may overlap the first active contact AC1 in the third direction D3. The lower active contact LAC may be in contact with the source/drain pattern SD. The lower active contact LAC may penetrate the substrate 10 in the third direction D3. The lower active contact LAC may include a conductive material.

The channel patterns 31 may include a first channel pattern 31_1 and a second channel pattern 31_2 overlapping each other in the third direction D3, and a third channel pattern 31_3 and a fourth channel pattern 31_4 overlapping each other in the third direction D3.

The third channel pattern 31_3 may be disposed at the same level as the first channel pattern 31_1, and may be spaced apart from the first channel pattern 31_1 in the first direction D1. The fourth channel pattern 31_4 may be disposed at the same level as the second channel pattern 31_2, and may be spaced apart from the second channel pattern 31_2 in the first direction D1.

The gate patterns GE1 may include a first gate pattern GE1_1 disposed between the first and second channel patterns 31_1 and 31_2, and a second gate pattern GE1_2 disposed between the third and fourth channel patterns 31_3 and 31_4. The second gate pattern GE1_2 may be disposed at the same level as the first gate pattern GE1_1, and may be spaced apart from the first gate pattern GE1_1 in the first direction D1. The first gate pattern GE1_1 may overlap the first and second channel patterns 31_1 and 31_2 in the third direction D3. The second gate pattern GE1_2 may overlap the third and fourth channel patterns 31_3 and 31_4 in the third direction D3.

The connection conductive patterns 21 may include a first connection conductive pattern 21_1 and a second connection conductive pattern 21_2 spaced apart from each other in the first direction D1 with the first and second channel patterns 31_1 and 31_2 and the first gate pattern GE1_1 therebetween. The connection conductive patterns 21 may include a third connection conductive pattern 21_3 and a fourth connection conductive pattern 21_4 spaced apart from each other in the first direction D1 with the third and fourth channel patterns 31_3 and 31_4 and the second gate pattern GE1_2 therebetween.

The first connection conductive pattern 21_1 and the second connection conductive pattern 21_2 may be electrically connected to the first gate pattern GE1_1. The first connection conductive pattern 21_1 and the second connection conductive pattern 21_2 may be in contact with the first gate pattern GE1_1. The third connection conductive pattern 21_3 and the fourth connection conductive pattern 21_4 may be electrically connected to the second gate pattern GE1_2. The third connection conductive pattern 21_3 and the fourth connection conductive pattern 21_4 may be in contact with the second gate pattern GE1_2. The first connection conductive pattern 21_1 and the second connection conductive pattern 21_2 may be spaced apart from the first and second channel patterns 31_1 and 31_2. The third connection conductive pattern 21_3 and the fourth connection conductive pattern 21_4 may be spaced apart from the third and fourth channel patterns 31_3 and 31_4. The first and second channel patterns 31_1 and 31_2 and the first gate pattern GE1_1 may be disposed between the upper surface 21_U and the lower surface 21_L of each of the first and second connection conductive patterns 21_1 and 21_2.

The source/drain patterns SD may include a first source/drain pattern SD1 connected to the first and second channel patterns 31_1 and 31_2 and a second source/drain pattern SD2 connected to the third and fourth channel patterns 31_3 and 31_4.

The mask patterns MP may include a first mask pattern MP1 overlapping the first and second channel patterns 31_1 and 31_2 and the first gate pattern GE1_1 in the third direction D3, and a second mask pattern MP2 overlapping the third and fourth channel patterns 31_3 and 31_4 and the second gate pattern GE1_2 in the third direction D3.

Referring to FIGS. 1F, 1G and 1H, the connection conductive pattern 21 may include a lower portion 21a and an upper portion 21b. The lower portion 21a of the connection conductive pattern 21 may include a first sidewall portion 21a1 and second sidewall portions 21a2. The second sidewall portions 21a2 may be connected to the first sidewall portion 21a1. The second sidewall portions 21a2 may be spaced apart from each other in the second direction D2.

A first sidewall 21a1_S1 of the first sidewall portion 21a1 may be in contact with a sidewall GE1_S of the gate pattern GE1, a sidewall GE2_S of the upper gate pattern GE2 and a sidewall GI_S of the gate insulating layer GI. A first sidewall 21a2_S1 of the second sidewall portion 21a2 may be in contact with a first sidewall 23_S1 of the second spacer 23. A second sidewall 23_S2 of the second spacer 23 may be in contact with a first sidewall 22_S1 of the first spacer 22. A second sidewall 22_S2 of the first spacer 22 may be in contact with the filling insulating layer 53. The first sidewall 23_S1 and the second sidewall 23_S2 of the second spacer 23 may be opposed to each other. The first sidewall 22_S1 and the second sidewall 22_S2 of the first spacer 22 may be opposed to each other.

The interposed portion 42 of the cover insulating layer 40 may include a first part 42a and second parts 42b. The first part 42a of the interposed portion 42 may be in contact with the first sidewall portion 21a1 and the second sidewall portions 21a2. The first part 42a of the interposed portion 42 may be disposed between the second parts 42b of the interposed portion 42. The second part 42b of the interposed portion 42 may be in contact with the second sidewall portion 21a2. A width in the first direction D1 of the first part 42a of the interposed portion 42 may be greater than a width in the first direction D1 of the second part 42b of the interposed portion 42.

The first part 42a of the interposed portion 42 may include a first sidewall 42a_S1 in contact with the second sidewall 21a2_S2 of the second sidewall portion 21a2, and a second sidewall 42a_S2 in contact with the second sidewall 21a1_S2 of the first sidewall portion 21a1. The second part 42b of the interposed portion 42 may include a first sidewall 42b_S1 in contact with the first sidewall 23_S1 of the second spacer 23, and a second sidewall 42b_S2 in contact with the third sidewall 21a2_S3 of the second sidewall portion 21a2. The third sidewall 21a1_S3 of the first sidewall portion 21a1 may be in contact with the first sidewall 23_S1 of the second spacer 23.

The upper portion 21b of the connection conductive pattern 21 may include a first sidewall 21b_S1 in contact with the first part 42a of the interposed portions 42, and a second sidewall 21b_S2 in contact with a sidewall MP_S of the mask pattern MP.

The second sidewall 21b_S2 of the upper portion 21b of the connection conductive pattern 21 and the first sidewall 21a1_S1 of the first sidewall portion 21a1 of the connection conductive pattern 21 may be connected to each other, and may cross each other. An angle between the second sidewall 21b_S2 of the upper portion 21b of the connection conductive pattern 21 and an upper surface of the substrate 10 may be different from an angle between the first sidewall 21a1_S1 of the first sidewall portion 21a1 of the connection conductive pattern 21 and the upper surface of the substrate 10.

The first sidewall 21b_S1 of the upper portion 21b of the connection conductive pattern 21 and the second sidewall 21a1_S2 of the first sidewall portion 21a1 of the connection conductive pattern 21 may be connected to each other, and may cross each other. An angle between the first sidewall 21b_S1 of the upper portion 21b of the connection conductive pattern 21 and the upper surface of the substrate 10 may be different form an angle between the second sidewall 21a1_S2 of the first sidewall portion 21a1 of the connection conductive pattern 21 and the upper surface of the substrate 10.

A sidewall 31_S of the channel pattern 31, a portion of a lower surface 31_L and a portion of an upper surface 31_U of the channel patterns 31 may be in contact with the source/drain pattern SD. A sidewall 32_S of the upper channel pattern 32, a portion of a lower surface 32_L and a portion of an upper surface 32_U of the upper channel patterns 32 may be in contact with the upper source/drain pattern USD.

Since the semiconductor device according to some example embodiments includes the connection conductive pattern 21, a part electrically connecting the gate patterns GE1 and GE2 may have a relatively constant width. Accordingly, uniformity of a critical voltage of a cell transistor may be improved.

Since the semiconductor device according to some example embodiments includes the connection conductive pattern 21, a distance in the first direction D1 between the channel pattern 31 and the interposed portion 42 of the cover insulating layer 40 may be relatively small. For example, the distance in the first direction D1 between the channel pattern 31 and the interposed portion 42 of the cover insulating layer 40 may be about 5.5 nm or less. Accordingly, a size of the semiconductor device may be reduced and/or minimized.

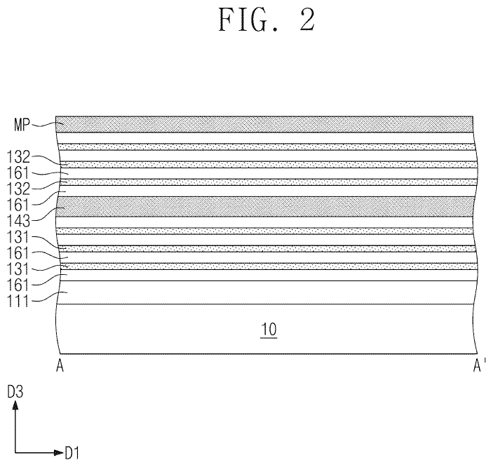

FIGS. 2, 3A, 3B, 4A, 4B, 5, 6A, 6B, 6C, 7A, 7B, 7C, 7D, 8A, 8B, 8C, 9A, 9B, 9C, 10A, 10B, 10C, 11A, 11B, 12A, 12B, 12C, 13A, 13B, 13C, 14A, 14B, 14C and 14D are diagrams for describing a method for manufacturing the semiconductor device according to FIGS. 1A to 1H.

Referring to FIG. 2, a substrate 10 may be provided. An insulating layer 111 may be provided on the substrate 10. The insulating layer 111 may include an insulating material.

Preliminary channel layers 131 and sacrificial layers 161 may be formed on the insulating layer 111. The preliminary channel layers 131 and the sacrificial layers 161 may be alternately stacked in the third direction D3. The preliminary channel layer 131 may include a semiconductor material. For example, the preliminary channel layer 131 may include a two-dimensional semiconductor material. The sacrificial layer 161 may include an insulating material. For example, the sacrificial layer 161 may include oxide.

According to some example embodiments, the preliminary channel layer 131 may be deposited on the sacrificial layer 161. According to some example embodiments, the preliminary channel layer 131 may be deposited on a deposition substrate, and may be transferred from the deposition substrate onto the sacrificial layer 161. According to some example embodiments, the preliminary channel layer 131 may be grown on the sacrificial layer 161.

An interlayer insulating layer 143 may be formed on the sacrificial layer 161. The interlayer insulating layer 143 may include an insulating material.

Preliminary upper channel layers 132 and the sacrificial layers 161 may be formed on the interlayer insulating layer 143. The preliminary upper channel layers 132 and the sacrificial layers 161 may be alternately stacked in the third direction D3. The preliminary upper channel layer 132 may include a semiconductor material. For example, the preliminary upper channel layer 132 may include a two-dimensional semiconductor material.

According to some example embodiments, the preliminary upper channel layer 132 may be deposited on the sacrificial layer 161. According to some example embodiments, the preliminary upper channel layer 132 may be deposited on the deposition substrate, and may be transferred from the deposition substrate to the sacrificial layer 161. According to some example embodiments, the preliminary upper channel layer 132 may be grown on the sacrificial layer 161.

A mask layer ML may be formed on the sacrificial layer 161. The mask layer ML may include an insulating material.

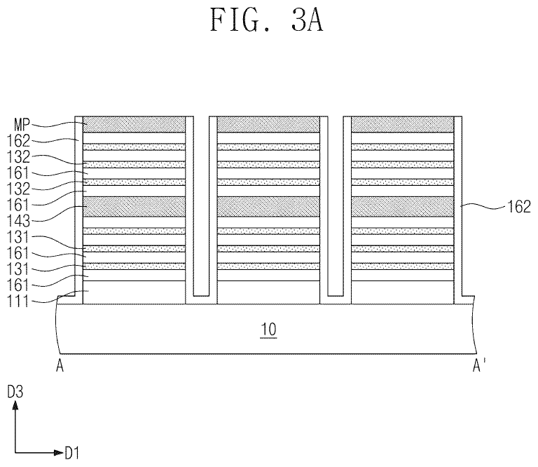

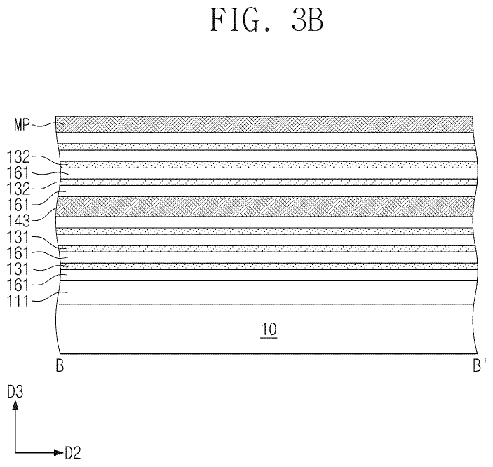

Referring to FIGS. 3A and 3B, the mask layer ML, the sacrificial layers 161, the preliminary upper channel layers 132, the interlayer insulating layer 143, preliminary channel layers 131 and the insulating layer 111 may be patterned. Each of the mask layer ML, the sacrificial layer 161, the preliminary upper channel layer 132, the interlayer insulating layer 143, the preliminary channel layers 131 and the insulating layer 111 may be divided into a plurality of pieces by patterning.

Liners 162 may be formed. Forming the liners 162 may include forming the liner 162 on the mask layer ML, the sacrificial layers 161, the preliminary upper channel layers 132, the interlayer insulating layer 143, the preliminary channel layers 131 and the insulating layer 111, and dividing the liner 162 into a plurality of liners 162 by removing upper portions of the liner 162. The liner 162 may include an insulating material.

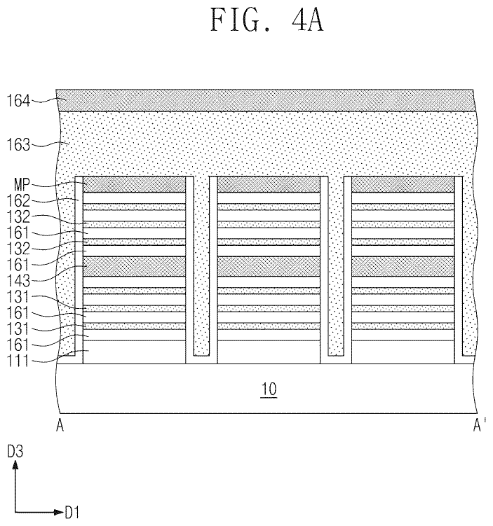

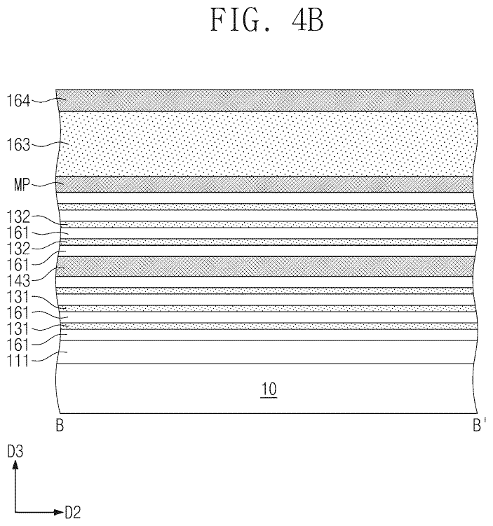

Referring to FIGS. 4A and 4B, a gate sacrificial layer 163 may be formed on the liner 162 and the mask layer ML. A gate mask layer 164 may be formed on the gate sacrificial layer 163. For example, the gate sacrificial layer 163 may include silicon. The gate mask layer 164 may include an insulating material.

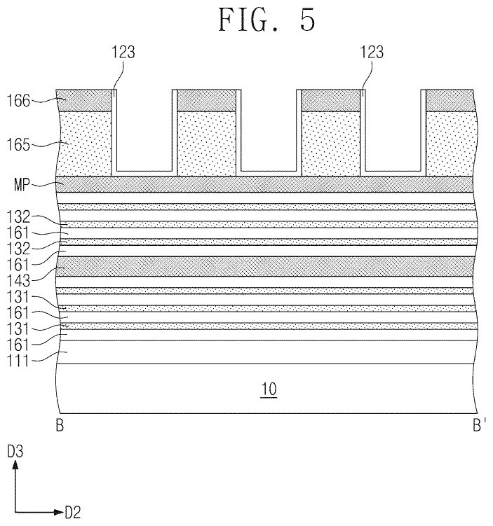

Referring to FIG. 5, the gate sacrificial layer 163 and the gate mask layer 164 may be patterned. The gate sacrificial layer 163 may be patterned to be divided into a plurality of gate sacrificial patterns 165. The gate mask layer 164 may be patterned to be divided into a plurality of gate mask patterns 166.

A preliminary spacer layer 123 may be formed on the mask layer ML, the gate sacrificial pattern 165 and the gate mask pattern 166. The preliminary spacer layer 123 may include an insulating material.

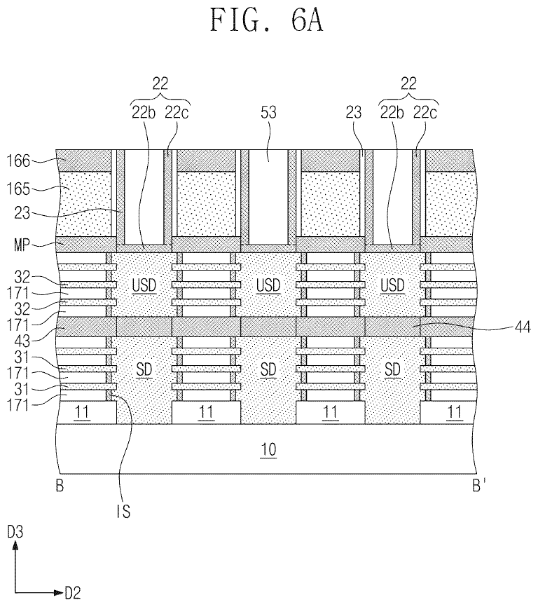

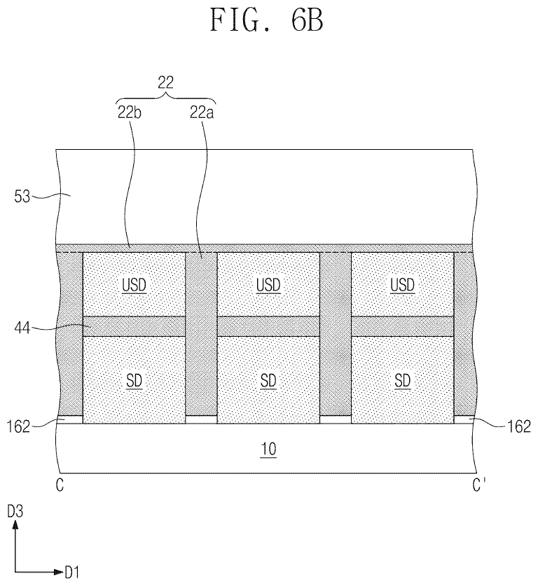

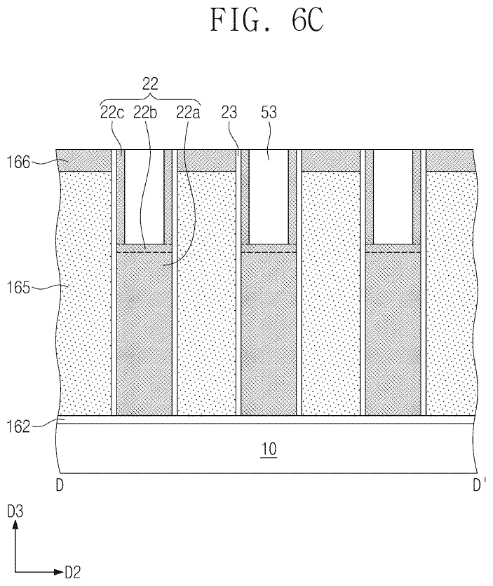

Referring to FIGS. 6A, 6B and 6C, the mask layer ML, the sacrificial layers 161, the preliminary upper channel layers 132, the interlayer insulating layer 143, the preliminary channel layers 131 and the insulating layer 111 may be patterned. Patterning the mask layer ML, the sacrificial layers 161, the preliminary upper channel layers 132, the interlayer insulating layer 143, the preliminary channel layers 131 and the insulating layer 111 may include performing an etching process using the gate mask pattern 166 and the preliminary spacer layer 123 as etching masks. The preliminary spacer layer 123 may be divided into a plurality of second spacers 23 in the etching process using the gate mask pattern 166 and the preliminary spacer layer 123 as the etching masks.

The mask layer ML may be patterned to be divided into a plurality of mask patterns MP. The sacrificial layer 161 may be patterned to be divided into a plurality of sacrificial patterns 171. The preliminary upper channel layer 132 may be patterned to be divided into a plurality of upper channel patterns 32. The interlayer insulating layer 143 may be patterned to be divided into a plurality of first interlayer insulating patterns 43. The preliminary channel layer 131 may be patterned to be divided into a plurality of channel patterns 31. The insulating layer 111 may be patterned to be divided into a plurality of insulating patterns 11.

The sacrificial patterns 171 may be selectively etched through sidewalls of the sacrificial patterns 171. The sacrificial pattern 171 may be selectively etched so that a width in the second direction D2 of the sacrificial pattern 171 may be smaller than a width in the second direction D2 of the channel pattern 31 and a width in the second direction D2 of the upper channel pattern 32.

Inner spacers IS may be formed. The inner spacers IS may be formed on the sacrificial pattern 171.

Source/drain patterns SD may be formed. According to some example embodiments, the source/drain patterns SD may be formed through an epitaxial growth process using the channel patterns 31 as seeds.

Second interlayer insulating patterns 44 may be formed. The second interlayer insulating pattern 44 may be formed on the source/drain pattern SD.

Upper source/drain patterns USD may be formed. According to some example embodiments, the upper source/drain patterns USD may be formed through an epitaxial growth process using the upper channel patterns 32 as seeds.

First spacers 22 may be formed. The first spacer 22 may be formed on the source/drain patterns SD and the upper source/drain patterns USD.

A filling insulating layer 53 may be formed on the first spacer 22.

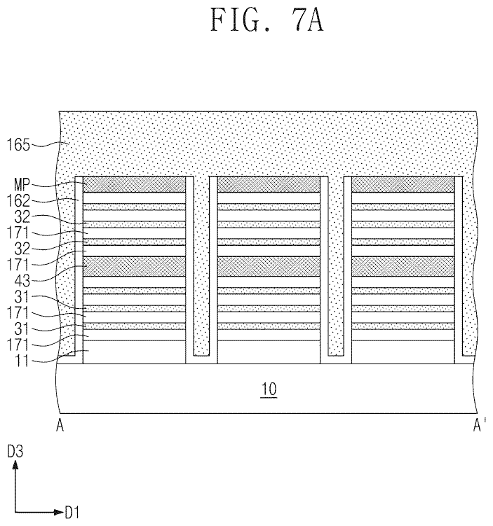

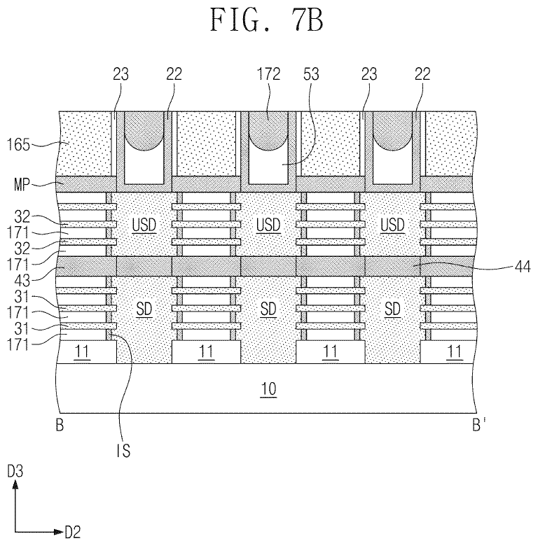

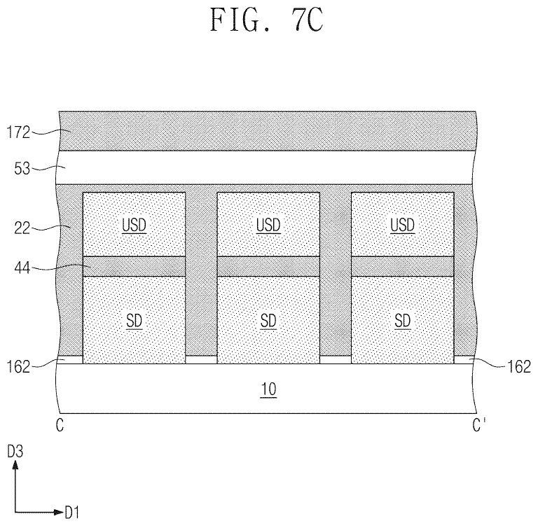

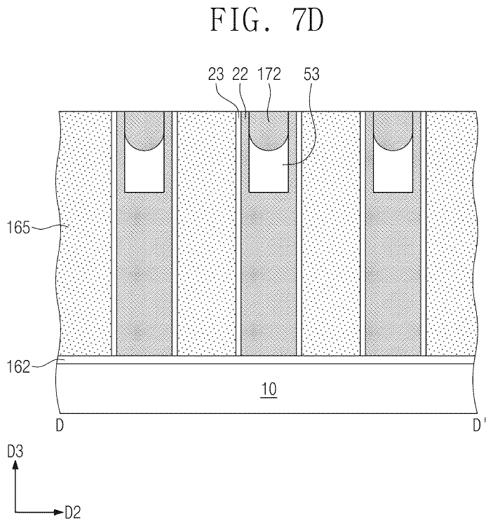

Referring to FIGS. 7A, 7B, 7C and 7D, the gate mask patterns 166 may be removed. The gate sacrificial pattern 165 may be exposed by removing the gate mask pattern 166. A capping layer 172 may be formed on the filling insulating layer 53. The capping layer 172 may include an insulating material.

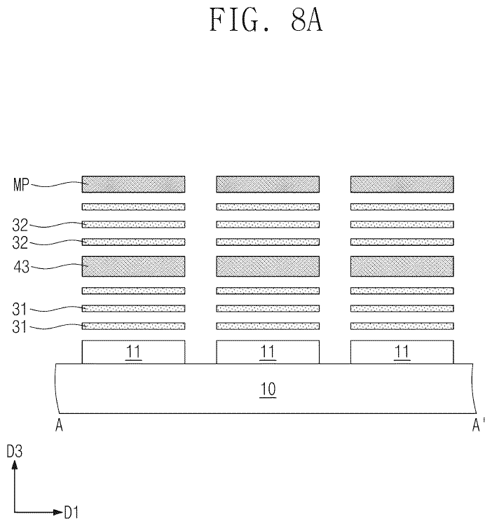

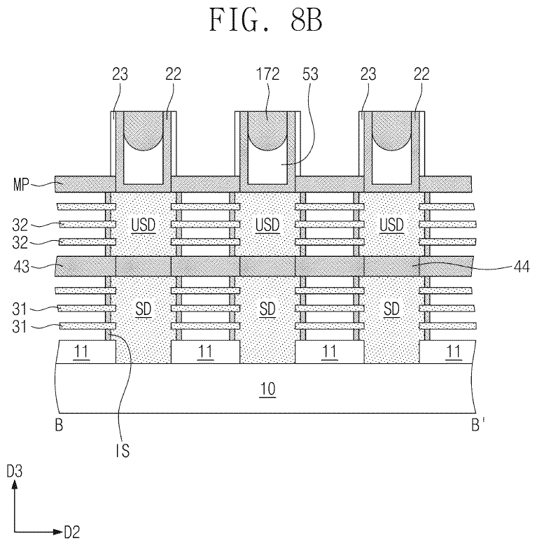

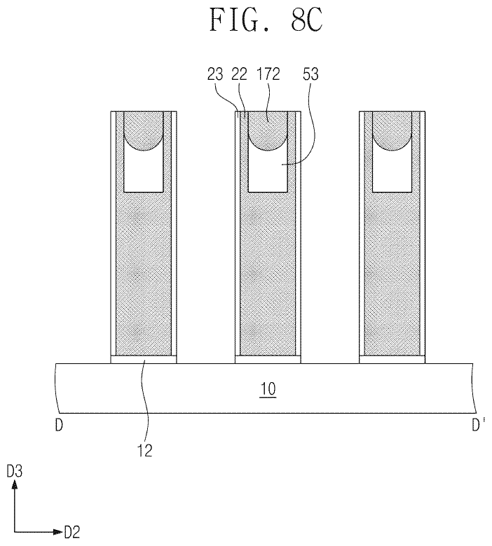

Referring to FIGS. 8A, 8B and 8C, the gate sacrificial patterns 165 may be removed. The sacrificial patterns 171 may be removed. Interposed patterns 12 may be formed by etching the liner 162 in a process of removing the sacrificial pattern 171.

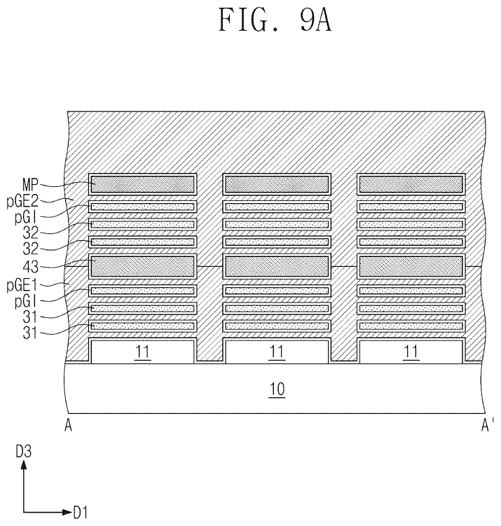

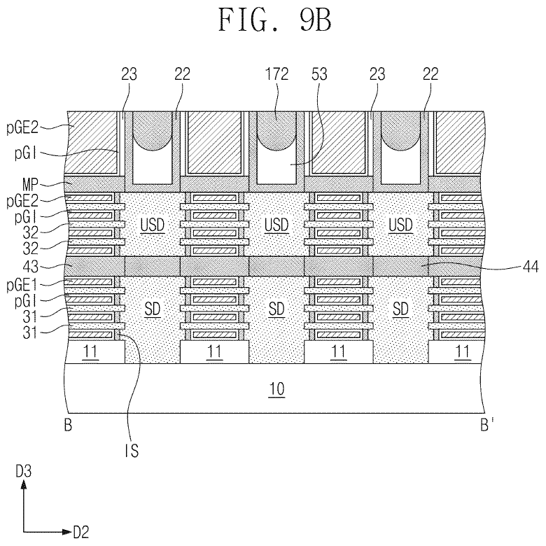

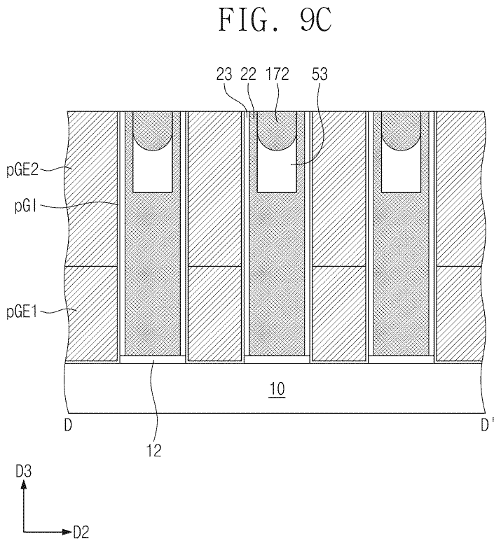

Referring to FIGS. 9A, 9B and 9C, preliminary gate insulating layers pGI may be formed. The preliminary gate insulating layers pGI may include an insulating material.

Preliminary gate layers pGE1 and preliminary upper gate layers pGE2 may be formed. The preliminary gate layers pGE1 and the preliminary upper gate layers pGE2 may include a conductive material.

The preliminary gate insulating layers pGI, the preliminary gate layers pGE1 and the preliminary upper gate layers pGE2 may fill empty spaces formed by removing the sacrificial patterns 171.

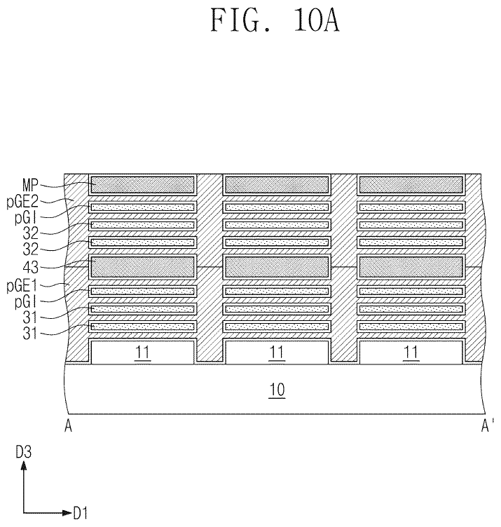

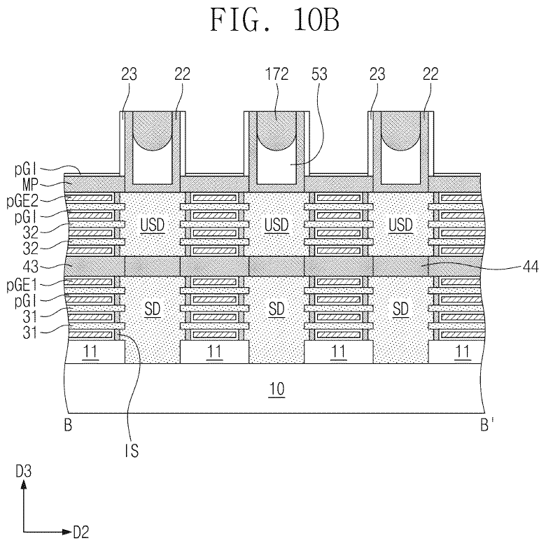

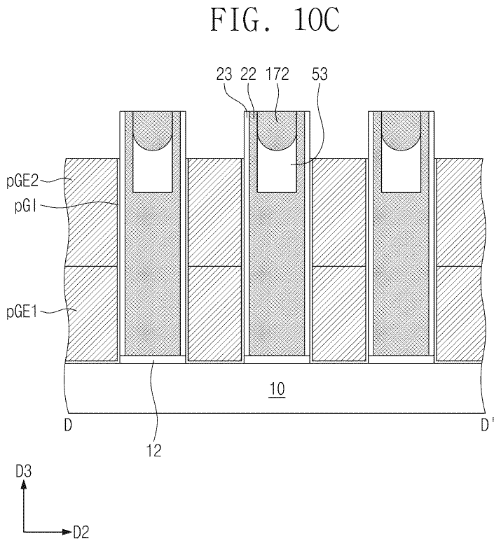

Referring to FIGS. 10A, 10B and 10C, the preliminary upper gate layer pGE2 may be etched. The preliminary gate insulating layer pGI disposed on an uppermost portion of the preliminary gate insulating layers pGI by etching the preliminary upper gate layer pGE2.

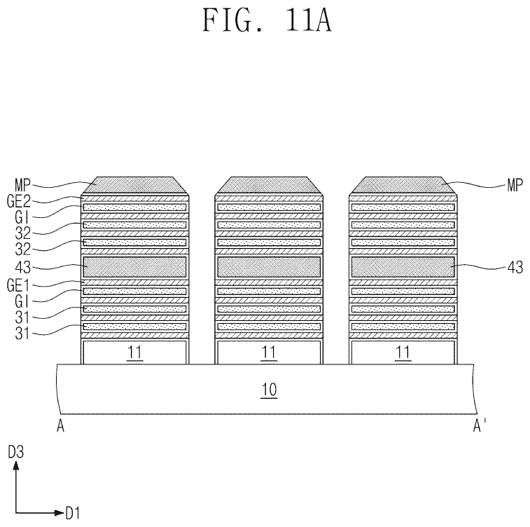

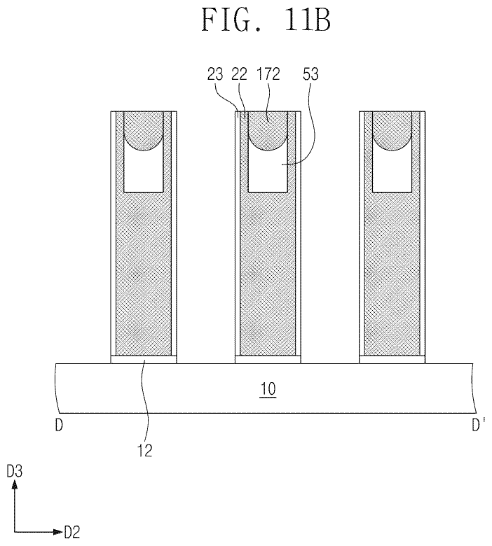

Referring to FIGS. 11A and 11B, the preliminary gate layer pGE1 and the preliminary upper gate layer pGE2 may be etched by using the mask pattern MP as an etching mask. The preliminary upper gate layers pGE2 may be etched to be divided into the upper gate patterns GE2. The preliminary gate layer pGE1 may be etched to be divided into the gate patterns GE1.

A shape of the mask pattern MP may be changed in a process of etching the preliminary gate layer pGE1 and the preliminary upper gate layer pGE2.

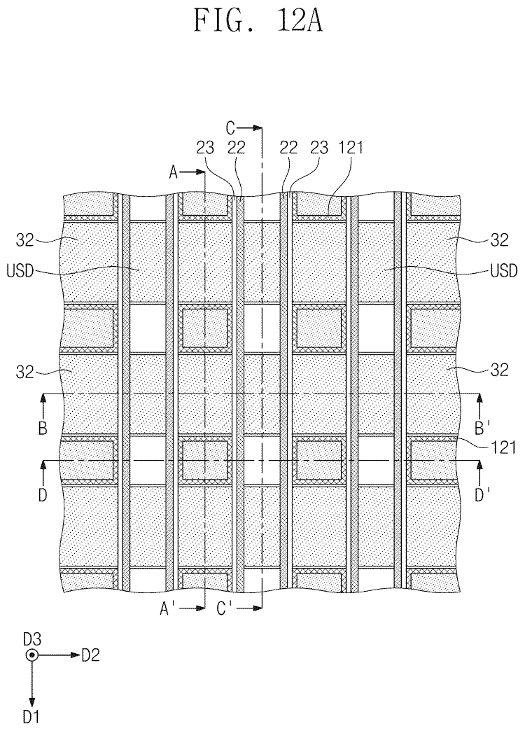

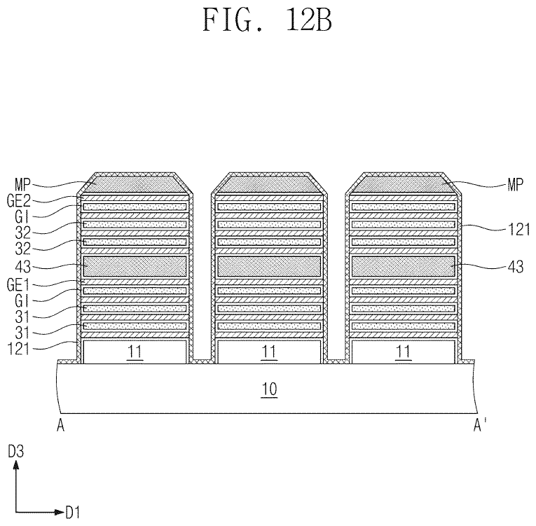

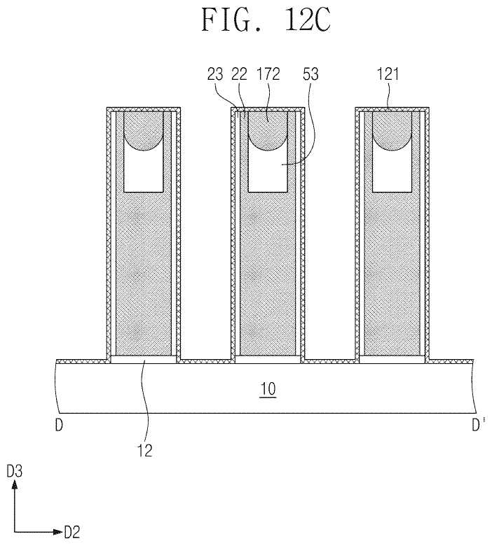

Referring to FIGS. 12A and 12B, a preliminary connection conductive layer 121 may be formed. The preliminary connection conductive layer 121 may be formed on the gate patterns GE1, the upper gate patterns GE2, the mask patterns MP and the second spacers 23. The preliminary connection conductive layer 121 may be in contact with sidewalls of the gate patterns GE1, the upper gate patterns GE2, the mask patterns MP and the second spacers 23, and upper surfaces of the mask patterns MP.

For example, the preliminary connection conductive layer 121 may be formed through a deposition process. The preliminary connection conductive layer 121 may include a conductive material. For example, the preliminary connection conductive layer 121 may include a two-dimensional conductive material.

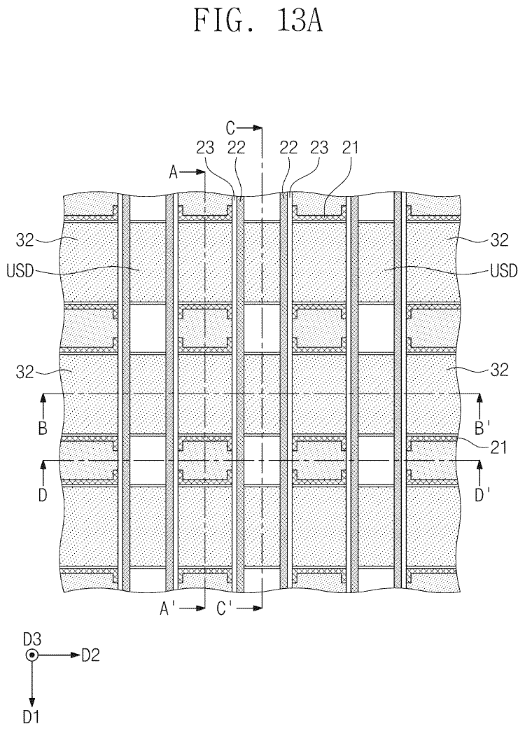

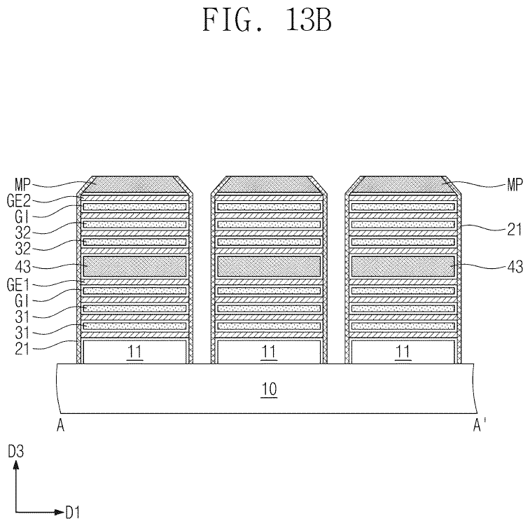

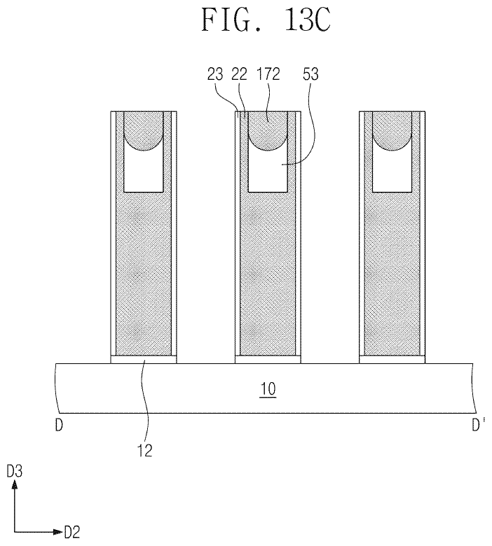

Referring to FIGS. 13A and 13B, connection conductive patterns 21 may be formed. According to some example embodiments, forming the connection conductive patterns 21 may include performing a first etching process of etching a part in contact with an upper surface of the mask pattern MP of the preliminary connection conductive layer 121, and a part in contact with an upper surface of the substrate 10, and performing a second etching process of etching a part in contact with a sidewall of the second spacer 23 of the preliminary connection conductive layer 121.

One connection conductive pattern 21 may be formed between two channel patterns 31 adjacent to each other in the first direction D1 by the first etching process. One connection conductive pattern 21 between two channel patterns 31 adjacent to each other in the first direction D1 may be divided into two connection conductive patterns 21 by the second etching process. Second sidewall portions 21a2 (see FIG. 1F) of the connection conductive pattern 21 may be formed by the second etching process.

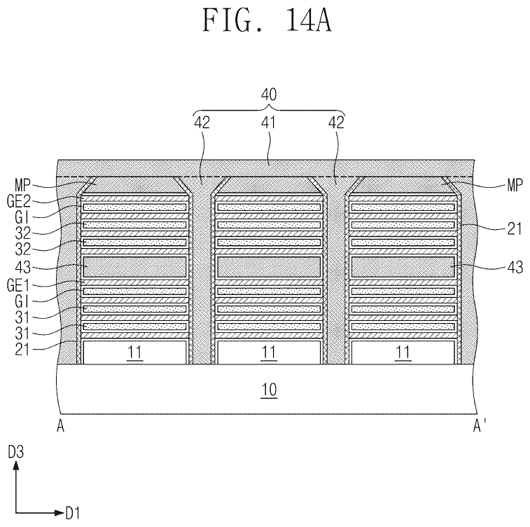

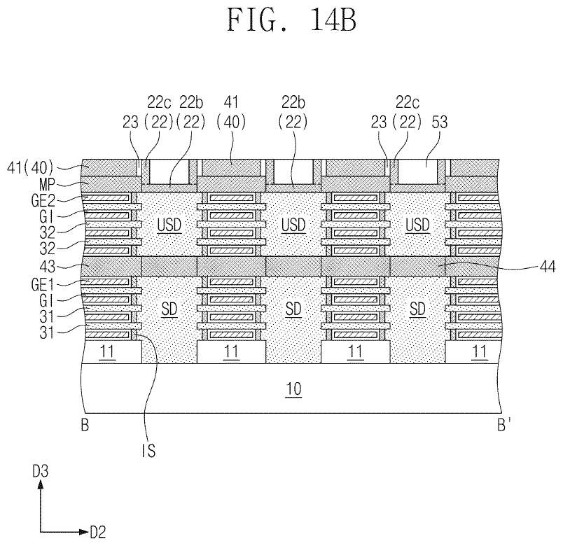

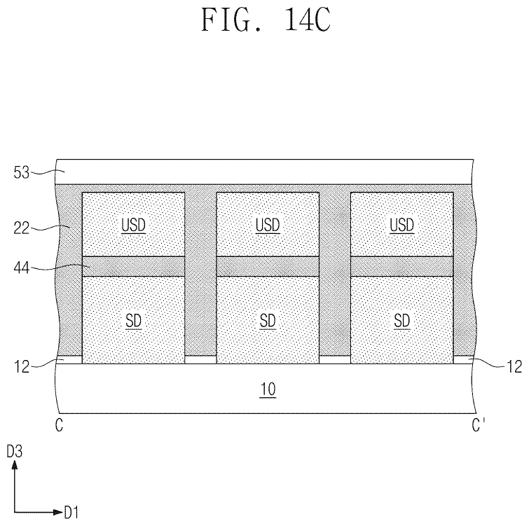

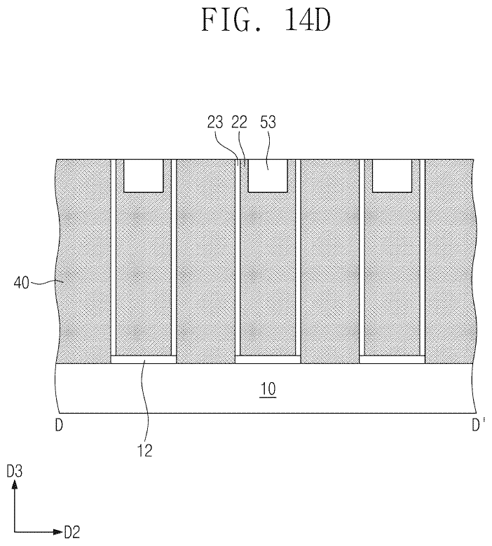

Referring to FIGS. 14A, 14B, 14C and 14D, a cover insulating layer 40 may be formed. An interposed portion 42 of the cover insulating layer 40 may be formed between the connection conductive patterns 21. An upper portion 41 of the cover insulating layer 40 may be formed on upper surfaces of the mask patterns MP.

After the cover insulating layer 40 is formed, a process of planarizing the cover insulating layer 40 may be performed. For example, the cover insulating layer 40 may be planarized by a chemical mechanical polishing process. An upper portion of the filling insulating layer 53, an upper portion of the third part 22c of the first spacer 22 and an upper portion of the second spacer 23 may be removed by the planarizing process of the cover insulating layer 40.

Referring to FIGS. 1A to 1E, active contacts AC1 and AC2, gate contacts GC and lower active contacts LAC may be formed.

Since the preliminary gate layer pGE1 and the preliminary upper gate layer pGE2 are etched using a self-align etching process using the mask pattern MP in the method for manufacturing the semiconductor device according to some example embodiments, a process of cutting the preliminary gate layer pGE1 and the preliminary upper gate layer pGE2 may be omitted, and the method for manufacturing the semiconductor device may be simplified.

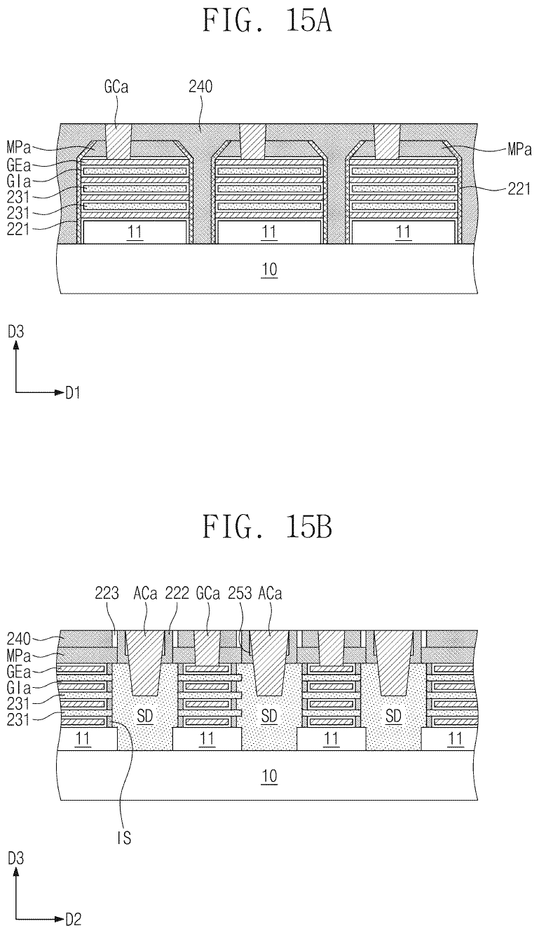

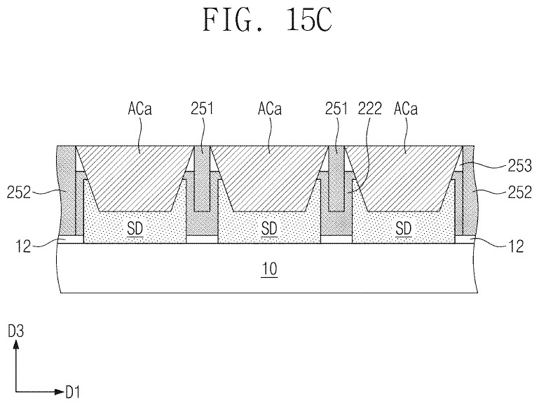

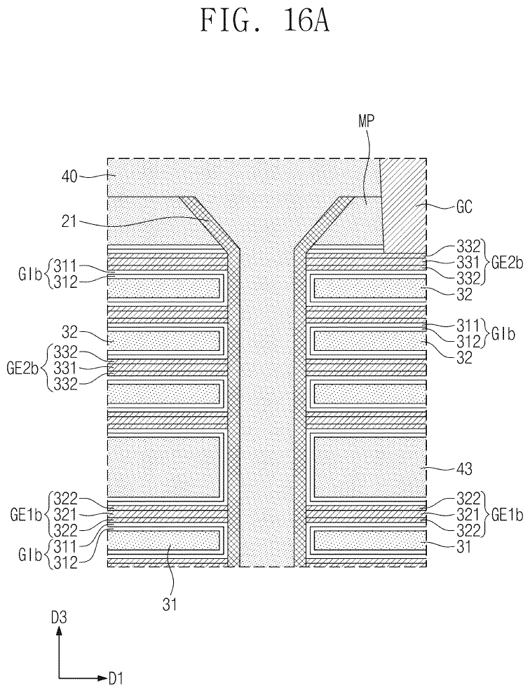

FIGS. 15A, 15B and 15C are cross-sectional views of a semiconductor device according to some example embodiments. The semiconductor device according to FIGS. 15A, 15B and 15C may be similar to the semiconductor device according to FIGS. 1A to 1H, except for what will be described later.

Referring to FIGS. 15A, 15B and 15C, the semiconductor device may include gate patterns GEa, gate insulating layers GIa, channel patterns 231 and a mask pattern MPa overlapping an insulating pattern 11 in the third direction D3.

Connection conductive patterns 221 spaced apart from each other in the first direction D1 may be provided with the insulating pattern 11, the gate patterns GEa, the gate insulating layers GIa, the channel patterns 231 and the mask pattern MPa overlapping in the third direction D3 therebetween.

A cover insulating layer 240 may be provided on the connection conductive patterns 221 and the mask patterns MP. A first spacer 222 on a source/drain pattern SD and a second spacer 223 on the mask pattern MPa may be provided. An active contact ACa may be in contact with the source/drain pattern SD. A filling insulating layer 253 may be provided on the first spacer 222.

First separation insulating layers 251 and second separation insulating layers 252 may be provided. The active contact ACa may be disposed between the first separation insulating layers 251, or between the first separation insulating layer 251 and the second separation insulating layer 252.

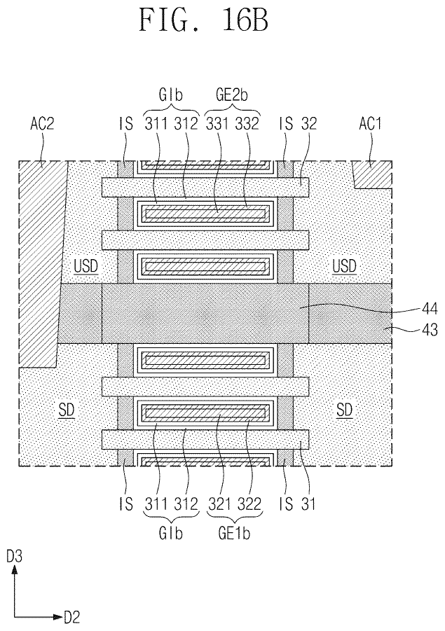

FIGS. 16A and 16B are enlarged cross-sectional views of a semiconductor device according to some example embodiments. The semiconductor device according to FIGS. 16A and 16B may be similar to the semiconductor device according to FIGS. 1A to 1H, except for what will be described later.

Referring to FIGS. 16A and 16B, a gate insulating layer GIb may include a first layer 311 and a second layer 312. The first layer 311 may be in contact with a gate pattern GE1b or an upper gate pattern GE2b. The second layer 312 may be in contact with a channel pattern 31 or an upper channel pattern 32. The first layer 311 and the second layer 312 may respectively include different insulating materials. The first layer 311 may be a high-dielectric layer having a greater dielectric constant than the second layer 312.

The gate pattern GE1b may include a first conductive layer 321 and a second conductive layer 322 surrounding the first conductive layer 321. The first conductive layer 321 and the second conductive layer 322 may respectively have different work-functions.

The upper gate pattern GE2b may include a third conductive layer 331 and a fourth conductive layer 332 surrounding the third conductive layer 331. The third conductive layer 331 and the fourth conductive layer 332 may respectively have different work-functions.

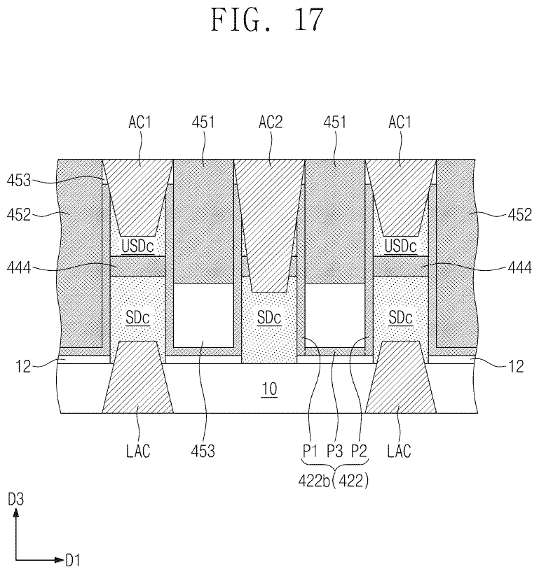

FIG. 17 is an enlarged cross-sectional view of a semiconductor device according to some example embodiments. The semiconductor device according to FIG. 17 may be similar to the semiconductor device according to FIGS. 1A to 1H, except for what will be described later.

Referring to FIG. 17, a first spacer 422 on source/drain patterns SDc, upper source/drain patterns USDc and second interlayer insulating patterns 444 may include a first part 422b provided between two source/drain patterns SDc adjacent to each other in the first direction D1, and between two upper source/drain patterns USDc adjacent to each other in the first direction D1.

The first part 422b of the first spacer 422 may include a first side portion P1, a second side portion P2 and a connection portion P3. The first side portion P1 and the second side portion P2 may be spaced apart from each other in the first direction D1. The first side portion P1 and the second side portion P2 may be connected to each other by the connection portion P3. Each of the first side portion P1 and the second side portion P2 may be in contact with the source/drain pattern SDc and the upper source/drain pattern USDc.

A filling insulating layer 453 may be partially provided between the first and second side portions P1 and P2 on the connection portion P3. The first separation insulating layer 451 may be provided between the first and second side portions P1 and P2 on the filling insulating layer 453. A second separation insulating layer 452 may be provided between the first and second side portions P1 and P2.

Since a semiconductor device according to some example embodiments of the inventive concepts includes a connection conductive pattern, uniformity of a critical voltage of a cell transistor may be improved.

Since the semiconductor device according to some example embodiments of the inventive concepts includes the connection conductive pattern, a size of the semiconductor device may be reduced and/or minimized.

Although some example embodiments have been described with reference to the accompanying drawings, it is understood that the present disclosure should not be limited to these example embodiments but various changes and modifications can be made by one ordinary skilled in the art within the spirit and scope of the example embodiments as hereinafter claimed. Therefore, it should be understood that the example embodiments described above are exemplary in all respects and are not intended to be limiting.

What is claimed is:

1. A semiconductor device comprising:
a first channel pattern and a second channel pattern at least partially overlapping;
a first gate pattern
between the first channel pattern and the second channel pattern, and
at least partially overlapping the first channel pattern and the second channel pattern;
a first connection conductive pattern and a second connection conductive pattern
spaced apart from each other in a first direction, and
the first channel pattern, the second channel pattern, and the first gate pattern between the first and second connection conductive patterns; and
a first source/drain pattern connected to the first channel pattern and the second channel pattern,
wherein the first connection conductive pattern and the second connection conductive pattern are electrically connected to the first gate pattern.

2. The semiconductor device of claim 1, wherein the first connection conductive pattern and the second connection conductive pattern comprise a two-dimensional conductive material.

3. The semiconductor device of claim 1, wherein the first channel pattern and the second channel pattern comprise a two-dimensional semiconductor material.

4. The semiconductor device of claim 1, further comprising:
a third channel pattern spaced apart from the first channel pattern in the first direction;
a fourth channel pattern spaced apart from the second channel pattern in the first direction;
a second gate pattern
between the third channel pattern and the fourth channel pattern, and
spaced apart from the first gate pattern in the first direction;
a third connection conductive pattern and a fourth connection conductive pattern spaced apart from each other in the first direction, and
the third channel pattern, the fourth channel pattern and the second gate pattern between the third and fourth connection conductive patterns; and
a second source/drain pattern connected to the third channel pattern and the fourth channel pattern,
wherein the third connection conductive pattern and the fourth connection conductive pattern are electrically connected to the second gate pattern.

5. The semiconductor device of claim 4, further comprising:
a cover insulating layer on the first to fourth connection conductive patterns,
wherein the cover insulating layer includes an interposed portion between the second connection conductive pattern and the third connection conductive pattern.

6. The semiconductor device of claim 5, wherein the second connection conductive pattern comprises
a first sidewall portion in contact with the first gate pattern,
second sidewall portions connected to the first sidewall portion, and
the second sidewall portions are spaced apart from each other in a second direction, the second direction crossing the first direction.

7. The semiconductor device of claim 6, wherein the interposed portion comprises,
a first part in contact with a sidewall of the first sidewall portion and in contact with first sidewalls of the second sidewall portions,
second parts contacting second sidewalls of the second sidewall portions, respectively,
the first part of the interposed portion is between the second parts of the interposed portion, and
a width in the first direction of the first part of the interposed portion is greater than a width in the first direction of each of the second parts of the interposed portion.

8. The semiconductor device of claim 4, further comprising:
a first spacer overlapping the first source/drain pattern and the second source/drain pattern,
wherein the first spacer includes
a first part between the first and second source/drain patterns,
a second part on the first part,
third parts spaced apart from each other on the second part in a second direction, the second direction crossing the first direction, and
a width of the first part of the first spacer in the first direction is same as a distance in the first direction between the first and second source/drain patterns.

9. A semiconductor device comprising:
a first channel pattern and a second channel pattern at least partially overlapping;
a first gate pattern
between the first channel pattern and the second channel pattern, and
overlapping the first channel pattern and the second channel pattern;
a first connection conductive pattern
spaced apart from the first channel pattern and the second channel pattern, and
electrically connected to the first gate pattern; and
a source/drain pattern connected to the first channel pattern and the second channel pattern,
wherein the first channel pattern, the second channel pattern, and the first gate pattern are between an upper surface and a lower surface of the first connection conductive pattern.

10. The semiconductor device of claim 9, wherein the first connection conductive pattern comprises a conductive material different from a material of the first gate pattern.

11. The semiconductor device of claim 9, wherein the first gate pattern comprises a first sidewall in contact with a sidewall of the first connection conductive pattern.

12. The semiconductor device of claim 11, further comprising:
a second connection conductive pattern in contact with a second sidewall of the first gate pattern,
wherein the first sidewall and the second sidewall of the first gate pattern are opposite each other, and
the first connection conductive pattern and the second connection conductive pattern are spaced apart from each other.

13. The semiconductor device of claim 12, wherein the first channel pattern and the second channel pattern are between the first connection conductive pattern and the second connection conductive pattern.

14. The semiconductor device of claim 9, further comprising:
a third channel pattern at least partially overlapping the first channel pattern, the first gate pattern, and the second channel pattern;
a second gate pattern
between the second channel pattern and the third channel pattern; and
at least partially overlapping the first channel pattern, the second channel pattern, the third channel pattern, and the first gate pattern,
wherein the second gate pattern is electrically connected to the first connection conductive pattern.

15. The semiconductor device of claim 9, further comprising:
a mask pattern at least partially overlapping the first channel pattern, the second channel pattern, and the first gate pattern,
wherein a sidewall of an upper portion of the first connection conductive pattern is in contact with a sidewall of the mask pattern.

16. The semiconductor device of claim 15, wherein
a sidewall of a lower portion of the first connection conductive pattern is in contact with the first gate pattern, and
the sidewall of the lower portion of the first connection conductive pattern and the sidewall of the upper portion of the first connection conductive pattern cross each other.

17. A semiconductor device comprising:
a first channel pattern and a second channel pattern at least partially overlapping;
a first gate pattern
between the first channel pattern and the second channel pattern, and
at least partially overlapping the first channel pattern and the second channel pattern;
a first connection conductive pattern and a second connection conductive pattern
spaced apart from each other in a first direction, and
the first channel pattern, the second channel pattern, and the first gate pattern between the first and second connection conductive patterns;
a first source/drain pattern connected to the first channel pattern and the second channel pattern;
a third channel pattern spaced apart from the first channel pattern in the first direction;
a fourth channel pattern spaced apart from the second channel pattern in the first direction, and overlapping the third channel pattern;
a second gate pattern
between the third channel pattern and the fourth channel pattern,
overlapping the third channel pattern and the fourth channel pattern, and
spaced apart from the first gate pattern in the first direction;
a third connection conductive pattern and a fourth connection conductive pattern
spaced apart from each other in the first direction, and
the third channel pattern, the fourth channel pattern and the second gate pattern between the third and fourth connection conductive patterns;
a second source/drain pattern connected to the third channel pattern and the fourth channel pattern;
a first spacer at least partially overlapping the first and second source/drain patterns;
a first mask pattern at least partially overlapping the first channel pattern, the second channel pattern, and the first gate pattern;
a second mask pattern at least partially overlapping the third channel pattern, the fourth channel pattern and the second gate pattern;
a second spacer on the first and second mask patterns and the first spacer; and
a cover insulating layer on the first and second mask patterns and the first to fourth connection conductive patterns.

18. The semiconductor device of claim 17, wherein the first mask pattern is between the first connection conductive pattern and the second connection conductive pattern.

19. The semiconductor device of claim 17, wherein an upper surface, a lower surface, and a sidewall of the first channel pattern are in contact with the first source/drain pattern.

20. The semiconductor device of claim 17, further comprising:
a first upper channel pattern and a second upper channel pattern each at least partially overlapping the first and second channel patterns;
a first upper gate pattern between the first upper channel pattern and the second upper channel pattern;
a third upper channel pattern and a fourth upper channel pattern at least partially overlapping the third and fourth channel patterns;
a second upper gate pattern between the third upper channel pattern and the fourth upper channel pattern;
a first upper source/drain pattern connected to the first and second upper channel patterns; and
a second upper source/drain pattern connected to the third and fourth upper channel patterns,
wherein the first upper gate pattern is electrically connected to the first and second connection conductive patterns,
the second upper gate pattern is electrically connected to the third and fourth connection conductive patterns,
the first and second upper channel patterns, and the first upper gate pattern are between the first and second connection conductive patterns, and
the third and fourth upper channel patterns, and the second upper gate pattern are between the third and fourth connection conductive patterns.
